(19) United States
(12) Patent Application Publication
(10) Pub. No.: US 2020/0411418 A1
(43) Pub. Date: Dec. 31, 2020

(54) SEMICONDUCTOR PACKAGE STRUCTURES FOR BROADBAND RF SIGNAL CHAIN

(71) Applicant: Texas Instruments Incorporated, Dallas, TX (US)

(72) Inventors: Yiqi Tang, Allen, TX (US); Liang Wan, Chengdu (CN); Siraj Akhtar, Richardson, TX (US); Rajen Manicon Murugan, Dallas, TX (US)

(21) Appl. No.: 16/916,062

(22) Filed: Jun. 29, 2020

Related U.S. Application Data
(60) Provisional application No. 62/867,659, filed on Jun. 27, 2019.

(51) Int. Cl. H01L 23/495; H01L 23/31; H01L 23/66

(52) U.S. Cl. CPC H01L 23/49531; H01L 23/3114; H01L 23/66; H01L 23/49541; H01L 23/49503

(57) ABSTRACT

A semiconductor package includes a die attach pad and a plurality of leads, and a die attached to the die attach pad and electrically coupled to the plurality of leads. The plurality of leads includes power leads and signal leads. An interconnecting trace is electrically coupled between a bond pad of the die and a via-pad. A via is coupled to the via-pad, and the via pad is coupled to one of the signal leads. A bypass trace includes a proximal end connected to the interconnecting trace and a distal end floating inside a mold compound of the semiconductor package.

### CROSS REFERENCE TO RELATED APPLICATIONS

This application claims the benefit of Provisional Application Ser. No. 62/867,659 entitled “SEMICONDUCTOR PACKAGE WITH PARASITICS COMPENSATION STRUCTURE”, filed Jun. 27, 2019, which is herein incorporated by reference in its entirety.

### TECHNICAL FIELD

This disclosure relates to a semiconductor package for broadband radio frequency (RF) signal chain with parasitics compensation structures within the package that impacts operating frequency of the semiconductor device within the package.

### BACKGROUND

Advances in higher speed and higher frequency require semiconductor packages with extremely high performance ranges. These packages and expected to provide not only physical connections of integrated circuit in the die of a device, but electrically beneficial structures. These requirements include ultra-low RLC (resistor, inductor and capacitor) parasitics, high frequency bandwidth, no circuit stability issue, LPF (low-pass filter) response at passband frequency, resonance free insertion loss for useable BW (bandwidth), and controllable broadband impedance from a package level.

### SUMMARY

In one example, a semiconductor package includes a die attach pad and a plurality of leads, and a die attached to the die attach pad and electrically coupled to the plurality of leads. The plurality of leads includes power leads and signal leads. An interconnecting trace is electrically coupled between a bond pad of the die and a via-pad. A via is coupled to the via-pad, and the via pad is coupled to one of the signal leads. A bypass trace includes a proximal end connected to the interconnecting trace and a distal end floating inside a mold compound of the semiconductor package.

In another example, a semiconductor package includes a die attach pad and a plurality of leads. A die is attached to the die attach pad and electrically coupled to the plurality of leads. The plurality of leads includes a power lead and a signal lead. A signal interconnecting trace is electrically coupled between a signal bond pad of the die and a signal via pad. A power interconnecting trace is electrically coupled between a power bond pad of the die and a power via pad, where the signal via pad is large in dimension than the power via pad. A signal via is between the signal via pad and the signal lead, and a power via between the power via pad and the power lead.

### BRIEF DESCRIPTION OF THE DRAWINGS

FIG. 1 is a perspective view of a semiconductor package, according to an example.

FIG. 2 is a magnified view of the device of FIG. 1.

FIG. 3 is a cross-sectional view of the various layers of the device of FIG. 1.

FIGS. 4A-4C are perspective views of various examples of a bypass trace according to an example.

FIGS. 5A-5F are perspective views of various examples of the bypass trace and FIG. 5G depicts their electrical performance as a function of frequency.

FIGS. 6A-6D are perspective views of various examples of the bypass trace that is linear and FIG. 6E depicts their electrical performance as a function of frequency.

FIGS. 7A-7F are perspective views of various examples of the interconnecting trace and FIG. 7G depicts their electrical performance as a function of frequency.

### DETAILED DESCRIPTION OF EXAMPLE EMBODIMENTS

In the drawings, like elements are denoted by like reference numerals for consistency.

Integrated circuit (IC) packages can be based on an emerging technology called a routable leadframe (RLF), molded interconnect substrate (MIS) or Copper Connection in Molding (C2IM). An RLF is single or multi-layer copper substrates formed by plating up the leads/traces/vias and filling the spaces between them with mold or laminate dielectric. The substrates are specialized for RLF technology. It can be described as a hybrid between leadframe and laminate substrate technologies.

The RLF is different than traditional substrates, as RLF technology includes pre-molded structure with one or more metal layers. Each layer is pre-configured generally with at least a top and a bottom copper plating layer with a dielectric layer between copper layers having vias to provide an electrical connections in the package. The RLF supports single- or multi-die configurations, enabling low-profile, fine-pitch packages. The RLF itself is developed and sold by various vendors, and a packaging house then generally takes the RLF and assembles an IC package around it including adding molding.

The RLF offers flexible design rules & metal thicknesses that further enable custom optimization for different applications (power, high current, high voltage, high frequency/speed, large pin count, etc.). Multi-layer manufacturing of the RLF enables for optimal electrical performance which includes controlled impedance, return path, and electrical shielding. Simplified material construction and flexibility in choices enable for lower coefficient of thermal expansion (CTE) mismatch and manufacturing risk compared to laminate substrate. RLF offers better electrical and thermal performance compared to standard wire bond or flip chip quad flat no-lead (QFN) packages. Further, RLF can have any-shape for a via for interconnection that offers better electrical performance compared to standard packages, including coax-type interconnect. Thermal performance improvements are another advantage of the flexibility offered by the RLF.

Various examples of the present disclosure provide a semiconductor package with parasitics compensation structure. The semiconductor package can be used for high speed amplifiers, such as operation amplifiers, trans-impedance amplifiers, RF amplifiers, and fully differential amplifiers (FDA) which can be used in 5G mobile applications. For example, in a single-ended to differential amplifier having 0.1-8 GHz active balun with superior linearity, the harmonic distortion and noise figure performance require high frequency along with package performance. The specification requirements for such amplifiers can be 0.1-8 GHz b/w, 4 dB NF, 20 dB Gain, Active balun, 350 mW PDC P1 dB>19 dBm, 01P3>35 dBm, HD2>60 dBc. From the package performance side, ultra-low RLC parasitics, LPF response at passband frequency, and circuit stability need to be ensured in 5G data applications. Wirebond QFN, HotRod QFN, and other similar packages have poor insertion or return loss and multiple resonances which lead to closed loop circuit amplifier instability and oscillation.

Various examples of the present disclosure overcome the above design challenges and additionally provide an electrically and thermally optimized design that can perform beyond required specifications. This disclosure provides differential input and output structures, within a flip chip RLF QFN package framework that can be tune to achieve broadband capability. For the purposes of this disclosure, tuning, or tunable includes varying dimensions of an interconnecting trace, bypass trace, or a pad in the signal path to impact an electrical performance as a function of frequency of the semiconductor package.

In general, a length of the interconnection trace impacts parasitics of the device which is illustrated in the following equations. For example,

$$len = \frac{λ}{4} \\ {f}_{r e s} = \frac{c}{λ \sqrt{∈}} = \frac{c}{4 \cdot len \cdot \sqrt{∈}}$$

Where, len is the trace length, fᵣₑₛ is the resonance frequency, λ is wavelength of signal, c is the speed of light in vacuum, and ∈ is the dielectric constant of the dielectric material in the RLF. In an alternative example, length can be replaced by any other dimension of the trace including width or height/thickness. It is clear from the above expression that length of the trace impacts an electrical performance as a function of frequency of the semiconductor package. In one example, a length or width or height (dimension) of an interconnecting trace is varied to impact (or compensates for the parasitic in the signal path) the resonant frequency. In another example, an additional bypass traces with various shapes are provided. In yet another example, a length or width or height or thickness of a signal pad to which an interconnecting trace is connected to, are varied that impacts the electrical performance as a function of frequency of the semiconductor package.

For the purposes of this disclosure a trace includes a single geometry within a layer of the RLF composed of a conductive material. A trace is different from a wire bond, a redistribution layer (RDL), a conductive portion in a layer in a PCB, or a conductive portion in a layer in any substrate other than in the RLF. In various examples of this disclosure, a trace can be either deposited or printed. Printing methods for traces includes inkjet printing, 3D printing, or screen printing.

For the purposes of this disclosure a length includes a measurement from one end of an interconnecting trace, a bypass trace or a signal pad to an opposite end. For example, length of the bypass trace includes the measurement from a proximal end of the bypass trace to the distal end of the bypass trace from a top view of the semiconductor package. A width includes a measurement between two parallel lines that define the length of an interconnecting trace, a bypass trace or a signal pad from a top view of the semiconductor package. A height or thickness includes a measurement between two ends of the interconnecting trace, the bypass trace or the signal pad from a cross-sectional view of the semiconductor package.

Various examples of the disclosure are explained using length as an example. Length of a component can be replaced with width, and height or thickness to enable the structures and are within the scope of this disclosure. Additionally, length, width, height or thickness of an interconnecting trace, or bypass trace, or a signal pad, or a signal via can be varied individually or in combination to achieve the parasitics compensation structures disclosed herein.

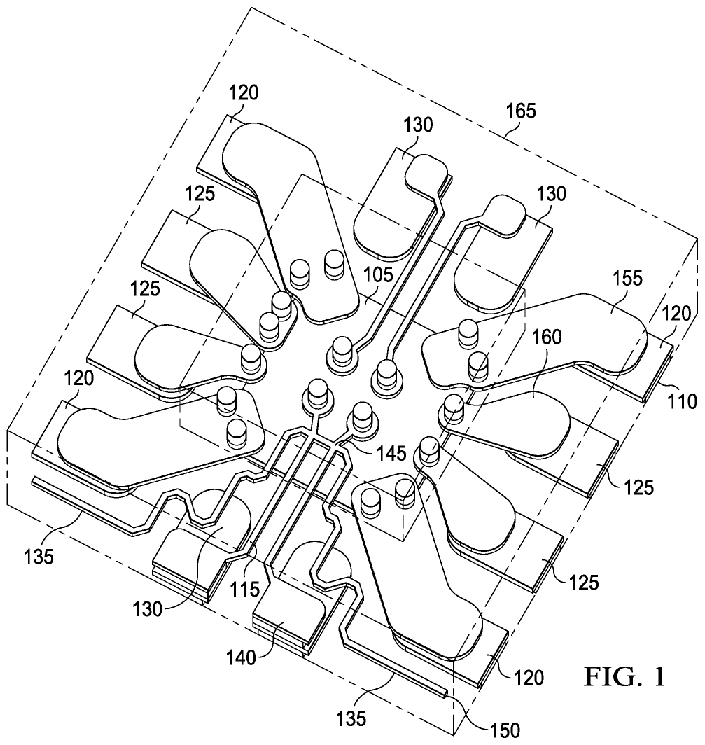

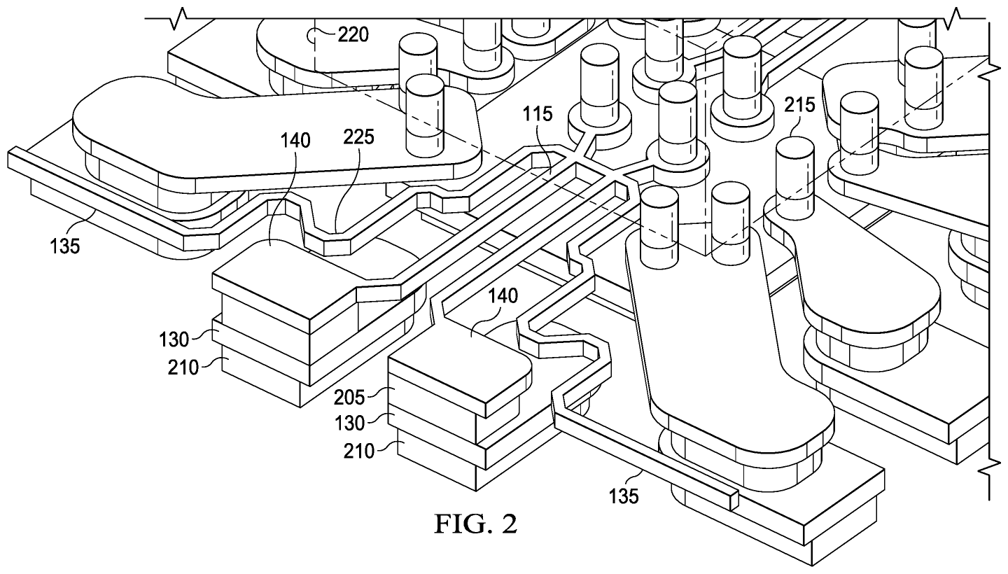

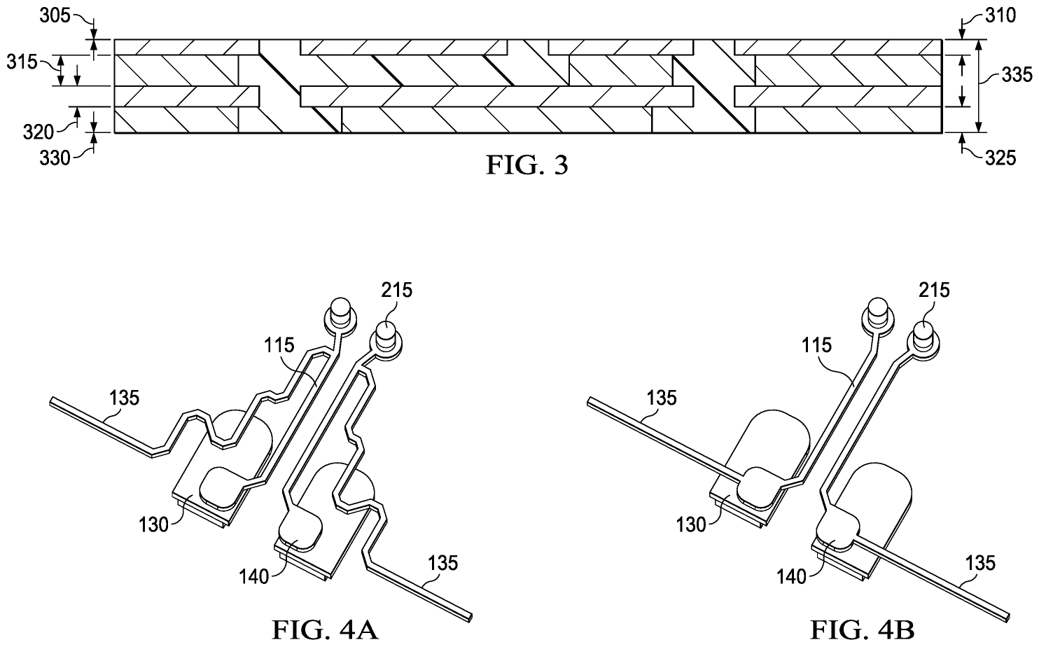

Referring now to FIG. 1 and FIG. 2, a perspective view of a package is illustrated. The package includes a die attach pad 105 and a plurality of leads 110, 125, 130. The die attach pad 105 and the plurality of leads 110, 125, 130 are part of the RLF. Additional insulating layers are present between the plurality of leads 110, 125, 130 and the die attach pad 105. The RLF includes various conductive and insulating layers as shown and explained later in the description related to FIG. 3. The insulating layers include a dielectric material. Other insulating materials such as mold compound, epoxy, organic or inorganic insulating materials are within the scope of this disclosure.

The plurality of leads include signal leads 130 (for signal transmission in and out of the die 220), power or control leads 125 (for power or control signal transmission in and of the die 220), and ground leads 120 (for ground voltage transmission). For the purposes of this illustration, the die 220 is shows as transparent with a rectangle in FIG. 1. In FIG. 2, the die 220 is shown transparent to which the bumps are connected to. An interconnecting trace 115 is electrically coupled between a bond pad of the die 220 and a via-pad 140. Specifically, interconnecting trace 115 is connected to a bump which is in turn connected to the bond pad of the die 220. The bond pad of the die is not shown in the figures. The bond pad is on the bottom surface of the die 220 in a flip chip configuration such as shown in FIGS. 1 and 2. A via 205 is coupled to the via-pad 140 on one side of the via 205. The other (opposite) side of the via 205 is connected to the leads 110, 125, 130. In a finished package, at least one side of the leads 110, 125, 130 are exposed from the package. A mold compound 150 covers portions of the die 220, leads 110, 125, 130, the traces (115, 135), the via pad 140, the via 205, forming sides of the package. Mold compound 165 is shown as transparent in FIGS. 1 and 2.

In one example, a bypass trace 135 is electrically connected to the interconnecting trace 115. The bypass trace 135 includes a proximal end 145 connected to the interconnecting trace 115 and a distal end 150 floating inside a mold compound of the semiconductor package. The distal end 150 of the bypass trace 135 extends towards a side or an edge of the semiconductor package as shown in FIGS. 1 and 2. The proximal end 145 includes the end that is connected to the interconnecting trace 115. The distal end 150 includes the end that is floating or free of any electrical connections directly connected to that end. The distal end 150 of the bypass trace 135 contacts with the mold compound 165 of the package.

The bypass trace 135 and the interconnecting trace 115 include a conductive material, for example a metal or a metal alloy. The bypass trace 135 and the interconnecting trace 115 include an additional coating of a metal alloy in addition to the base conductive material. An example of the conductive material includes copper. Other conductive materials that can be deposited and formed into a trace are within the scope of this disclosure (for example, gold, silver, etc.). In one example, the bypass trace 135, the interconnecting trace 115, the leads 110, 125, 130, the via pad 140, the via 205 are deposited using any suitable additive deposition techniques. In another example, the bypass trace 135, the interconnecting trace 115, the leads 110, 125, 130, the via pad 140, the via 205 are deposited using printing technologies such as 2D or 3D printing, inkjet printing, and screen printing.

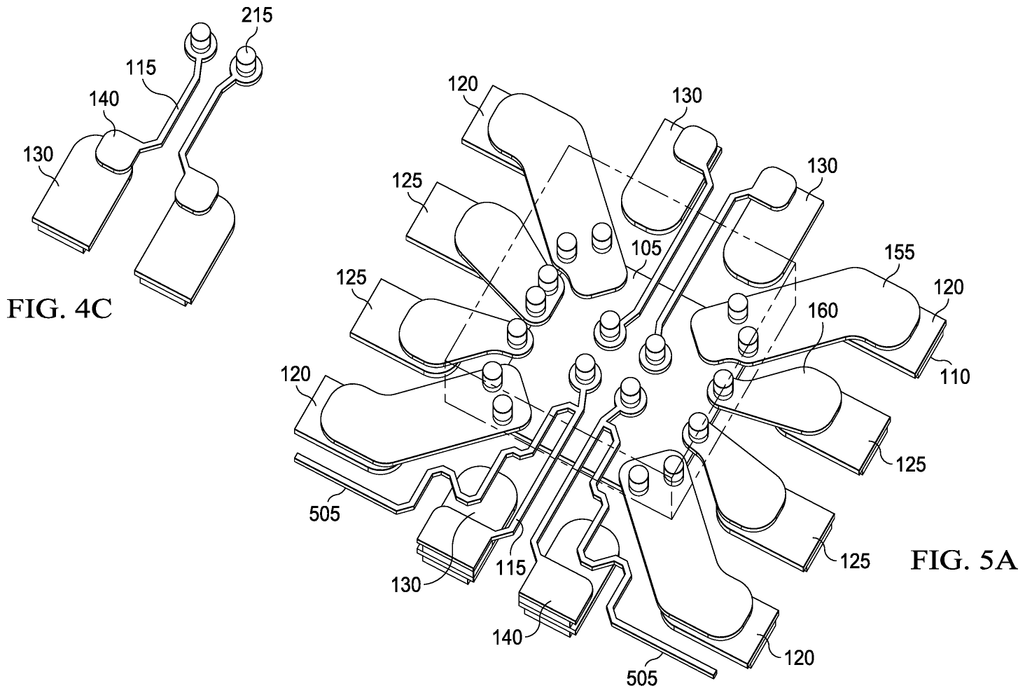

In one example, the bypass trace 135 is non-linear from a top view of the semiconductor package, for example as shown in FIG. 1. One or more kinks 225 in the bypass trace 135 make it non-linear. Non-linearity can be also achieved by designing the bypass trace 135 to be in different vertical layers of the RLF (as shown in FIG. 3), and in this case the bypass trace 135 is non-linear from a side view of the semiconductor package. As explained earlier, the length of the bypass trace 135 can be changed by adding more or less kinks 225 and tune the operating frequency of the device. The bypass trace 135 also includes chamfers with or without kinks. In the example of FIG. 1, the bypass trace 135 includes six kinks. In another example, the bypass trace 135 is linear without kinks as shown in FIG. 4B from a top view of the semiconductor package. The interconnecting trace 115 and the bypass trace 135 are coplanar from at least one view of the semiconductor package, for example a side view of the package. Stated differently, the interconnecting trace 115 and the bypass trace 135 are in the same layer of the RLF. Various layers are further explained in the description of FIG. 3 below.

The semiconductor package of FIG. 1 further includes additional traces connecting a power or control bond pad of the die (220, FIG. 2) to corresponding leads. For example, a power trace 160 connects a power bond pad of the die 220 to the power or control leads 125. A width of the power trace is more than a width of the interconnecting trace 115 or the bypass trace 135, from a top view of the semiconductor package. A ground trace 155 connects a ground bond pad of the die 220 to the power or control leads 120.

In one example, a length of the bypass trace is between 0.75 mm and 1.5 mm with a tunable range between 26 GHz and 34 GHz. In another example a length of the interconnecting trace is between 0.61 mm to 0.25 mm with a tunable range between 34 GHz and 42 GHz. In yet another example, a length of the bypass trace is between 0 mm to 0.5 mm with a tunable range between 34 GHz and 42 GHz. Other lengths and tunable ranges are within the scope of this disclosure. In one example, there are four signal leads, on opposite sides of the package as shown in FIG. 1. All four of the signal leads include interconnecting traces, however, only two interconnecting traces on one side (bottom side of the package as shown in the view of FIG. 1) includes a bypass trace 135. In this case, both bypass traces 135 are identical in nature and in mirror image with each other. In various examples, the package includes one, two, three or four bypass traces 135 depending on the application and tuning range.

In the magnified view of FIG. 1 in FIG. 2, signal via is shown connected to the signal pad 210. The chip 220 includes a bump 215 connected to the bond pad of the die 220. The interconnecting trace 115 is connected to the bump 215 using solder. The proximal end of the interconnecting trace 115 is connected to a section of the interconnecting trace 115 that surrounds the bump. The distal end 150 of the bypass trace 135 extends to an edge of the package as shown in FIG. 2, and ends beyond a plane along the edge of the interconnecting trace connecting to the power or control leads. The distal end 150 of the bypass trace 135 is adjacent to a plane along the edge of power or control lead that is exposed from the package.

Referring now to FIG. 3, a cross-sectional view of the various layers of the device of FIG. 1 is illustrated. Specifically four layers 335 of the RLF are illustrated in FIG. 3. Each layer includes metal traces and at least two layers include dielectric material or similar insulators. First layer is indicated with reference numeral 310, second layer with reference numeral 315, third layer with reference numeral 320, and fourth layer with reference numeral 325. Cross-sectional thickness of each layer and additional etch back layers are now provided. For example, an etch back thickness of a trace 305 is between 0-5 micrometers. Etch back refers to a recess etched on the exposed surface of the first 310 and fourth layer 325 to electrically disconnect adjacent parts of that layer from each other. A thickness of the first layer (via) is between 12 and 30 micrometers.

In one example, the thickness of the first layer is 15 micrometers. In one example, the thickness of the second layer 315 is 45 micrometers. A thickness of the third layer 320 is between 20 and 30 micrometers. In one example, the thickness of the third layer 320 is 25 micrometers. The thickness of the second layer 315 is 30 micrometers. An etch back thickness of a via is between 0-10 micrometers, with 5 micrometers as an example implementation. Total thickness of the RLF 335 is between 100-140 micrometers, with 120 micrometers as an example implementation. It is noted that the thickness measurements provided above are for illustrative purposes, and manufacturing tolerances of +/−10% is within the scope of this disclosure.

Referring now to FIGS. 4A-4C, various examples of the bypass trace 135 that can be implemented in FIG. 1 is illustrated. Each of FIGS. 4A-4C illustrates the bump 215, the interconnecting trace 115 electrically connected to the bump 215, the bypass trace 135 with a proximal end connected to the interconnecting trace 115, and a signal pad 210. FIG. 4A illustrates a magnified view of the bypass trace 135 in the implementation of FIG. 1. FIG. 4B illustrates a linear version of the bypass trace 135. In this example, a proximal end 145 of the bypass trace 135 is connected to the via pad 140 and the bypass trace extends substantially perpendicular to the orientation of the interconnecting trace 115, or an edge of the via pad 140. In the example of FIG. 4C, a bypass trace is absent.

Electrical performance as a function of frequency of the device can be tuned by varying the length of the interconnecting trace 115 or the signal pad in this example. The example of FIG. 4C when implemented in a package as in FIG. 1, the signal via pad 130 is large in dimension than the power via pad 125. Specifically, the signal via pad 130 is large in length than the power via pad from a top view of the semiconductor package. The length of the signal via pad 130 impacts the electrical performance as a function of frequency of the semiconductor package. In addition to the length, a width, or height of the signal via pad 130 can be varied to impact an electrical performance as a function of frequency of the semiconductor package with a tunable range between 34-42 GHz range. For example, width is in the range of 5 to 100 micrometers, thickness is in the range of 10 to 100 micrometers, and length is in the range of 0 micrometers to the longest trace that can fit in the package size dependent on the design.

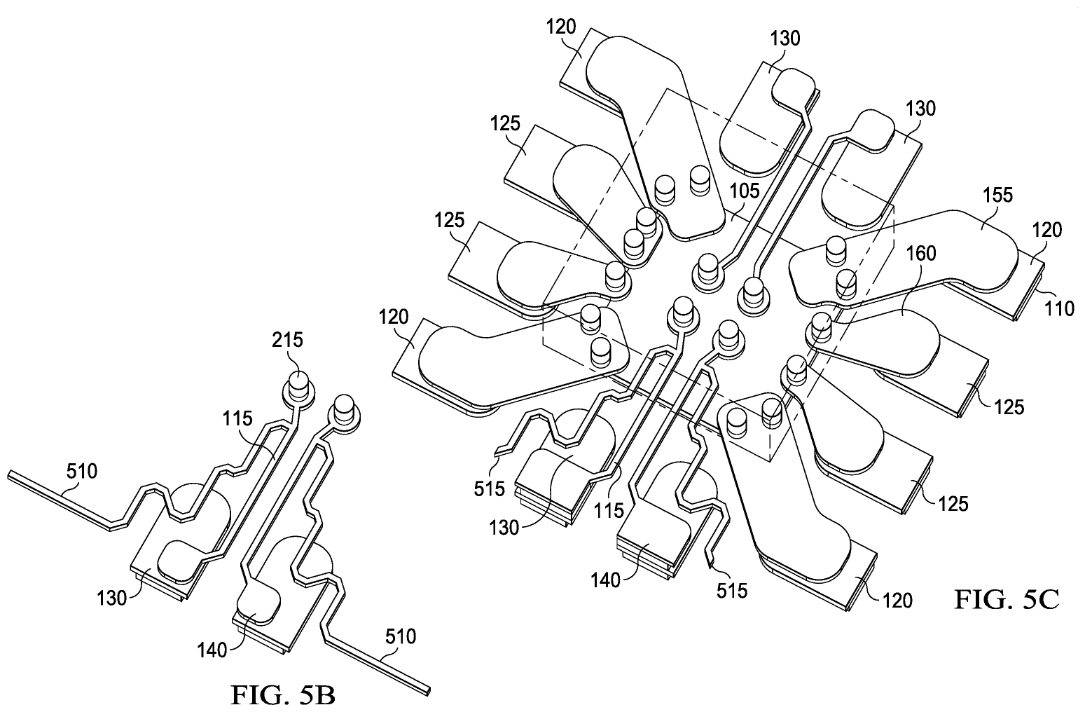

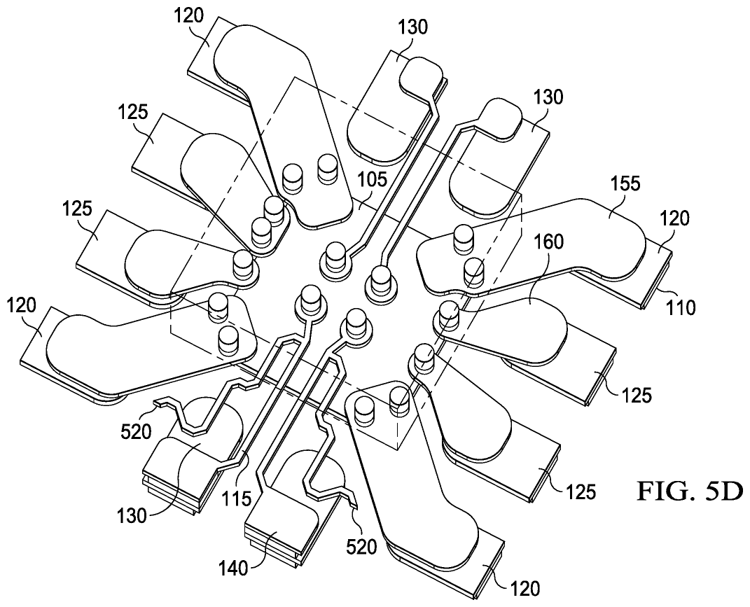

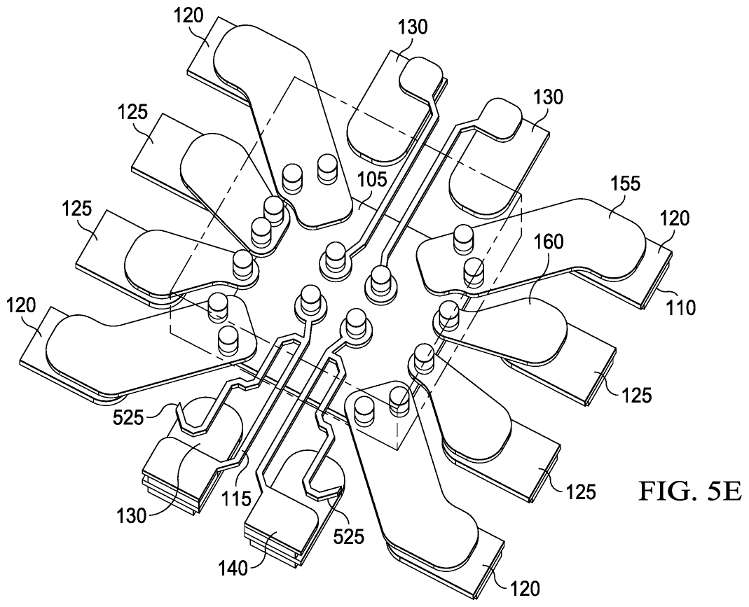

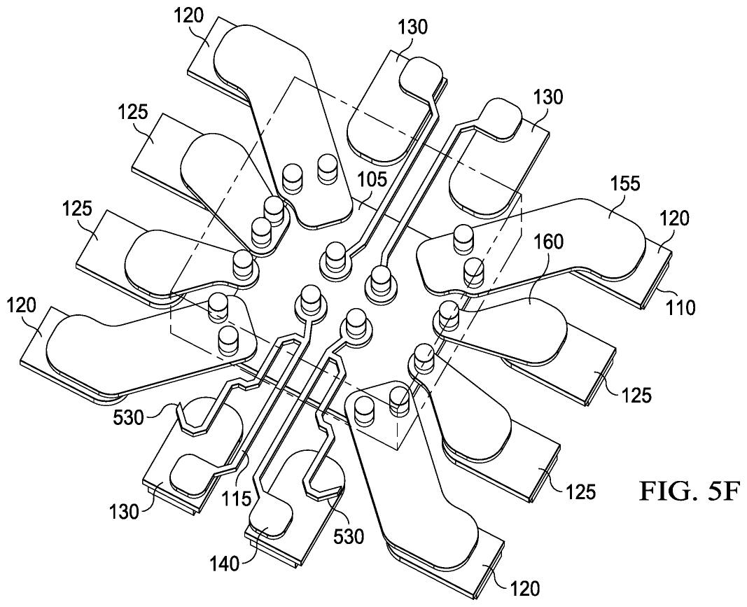

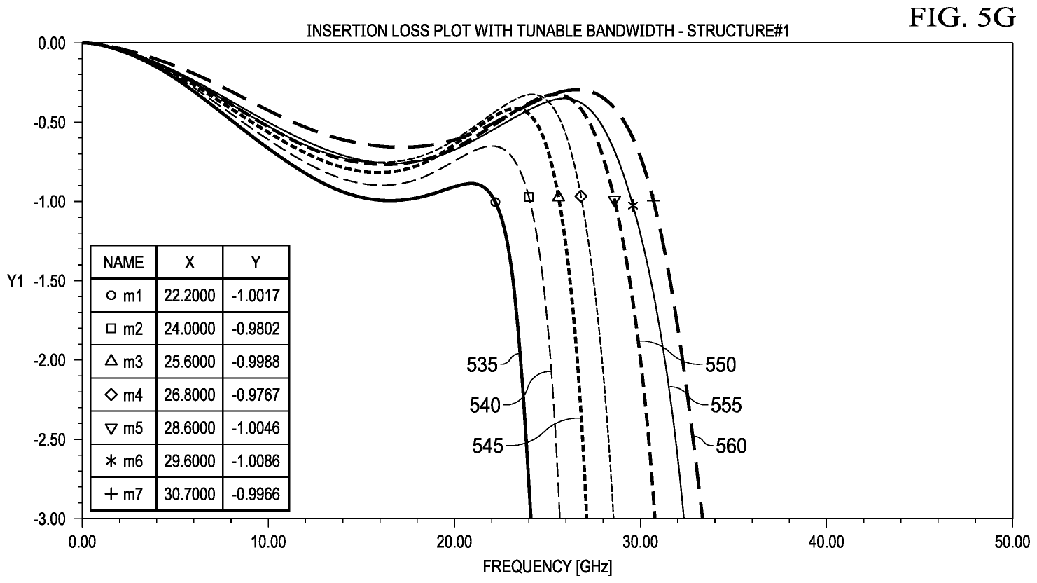

FIGS. 5A-5F are perspective views of various examples of the bypass trace 135 and FIG. 5F depicts their electrical performance as a function of frequency. In the example of FIG. 5A, the length of the bypass trace 505 is approximately 1.5 mm. In the example of FIG. 5A, the length of the bypass trace 510 is approximately between 1.2 to 1.3 mm. In the example of FIG. 5A, the length of the bypass trace 515 is approximately between 1.05 mm. In this case, the bypass trace 515 does not extend all the way to the edge of the package. Bypass traces 520, 525 of smaller lengths, for example 0.9 mm and 0.75 mm respectively as illustrated in FIGS. 5D and 5E. The example of FIG. 5F shows no bypass trace and a smaller via pad compared to that of in FIGS. 5A-5E. In one example, the dimensions of the smaller via pad are 150 um×150 um with 50 um chamfer. Each of the examples in FIGS. 5A-5F has a specific electrical performance as a function of frequency as illustrated in FIG. 5G. Therefore, these specific parameters (i.e. length, width, and thickness) are critical for tuning appropriate frequency bands for optimal performance as shown in FIG. 5G, 530-565 for the structures of FIGS. 5A-5F respectively.

The insertion loss plot of FIG. 5F illustrates the power loss caused by the package in a signal chain system. At DC the package is expected to introduce minimal loss. From DC up to the cut-off frequency, the insertion loss are maintained above −1 dB performance. The cut off frequency is defined such that the insertion loss is above −1 dB. After cut-off frequency, the insertion loss increases drastically so as to create the low-pass filter performance desired by the circuit device. The parameters of traces (length, width and thickness) in this disclosure can be selected such that the cut-off frequency can be tuned according to the need of the circuit device being packaged. The lengths, widths, and thicknesses of various bypass traces illustrated in FIGS. 5A-5F may vary with manufacturing and tolerances of +/−10% are within the scope of this disclosure.

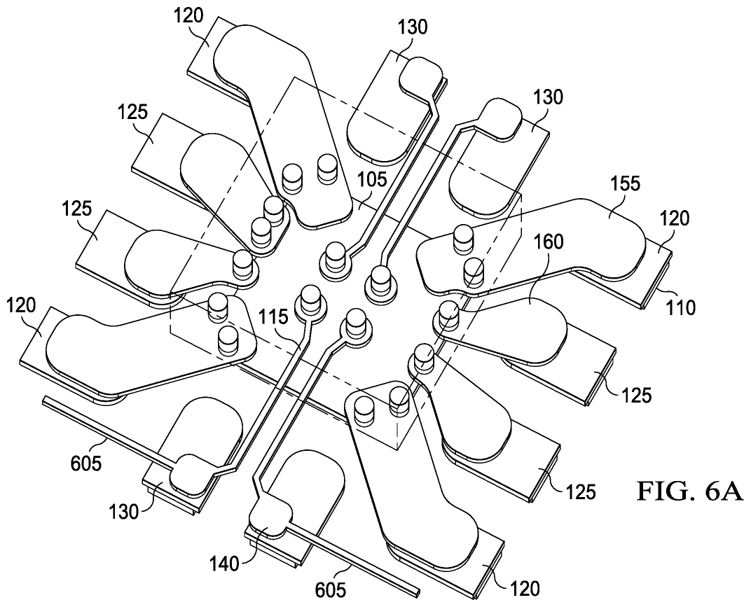

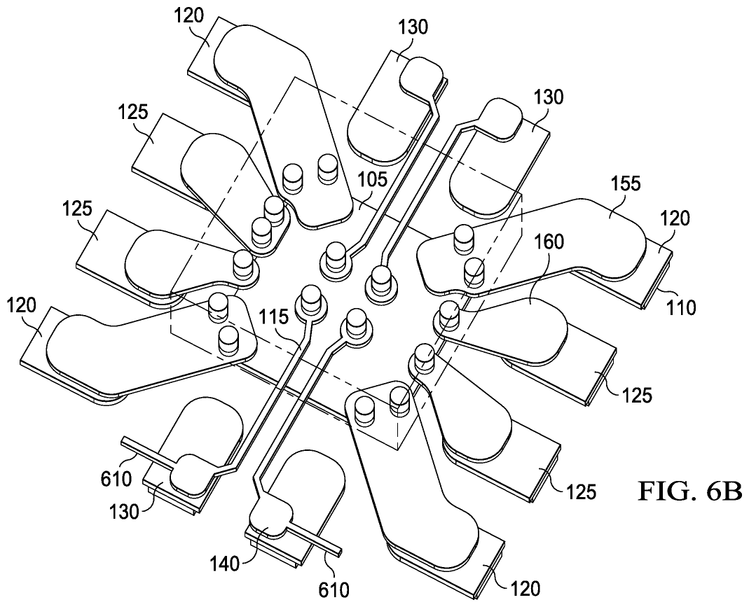

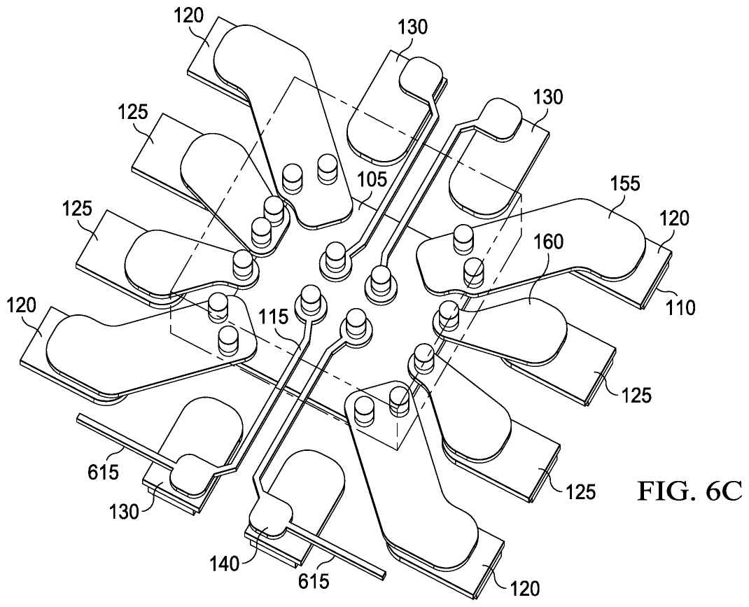

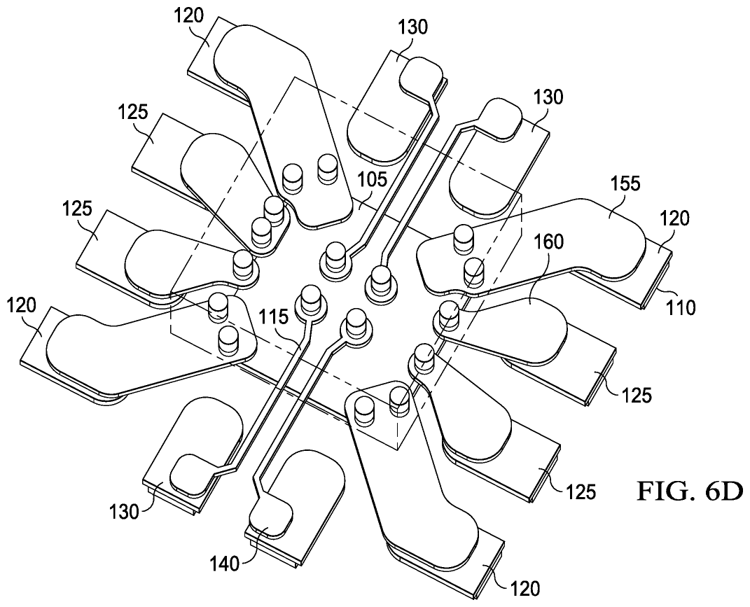

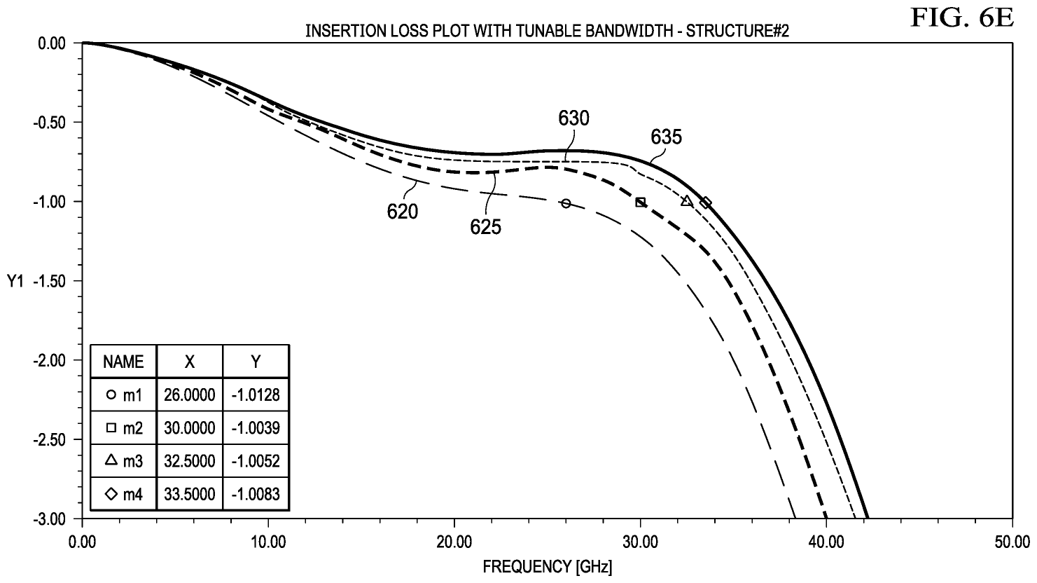

FIGS. 6A-6D are perspective views of various examples of the bypass trace 135 that is linear and FIG. 6E depicts their electrical performance as a function of frequency. Like in FIG. 5, various lengths of the bypass trace 135 are illustrated in FIGS. 6A-6D. For example, the bypass trace 605 of FIG. 6A is 0.5 mm, FIG. 6B, 610 is 0.2 mm, and FIG. 6C, 615 is 0.37 mm. FIG. 6D illustrates an example with no bypass trace. Each length of the bypass trace 135 in FIGS. 6A-6D has a specific electrical performance as a function of frequency as depicted in FIG. 6E. Therefore, these specific lengths are critical for tuning appropriate frequency bands for optimal performance to maintain control impedance as shown in FIG. 6E, 620-635 for the structures of FIGS. 6A-6D respectively. The lengths of various bypass traces illustrated in FIGS. 6A-6C may vary with manufacturing and tolerances of +/−10% are within the scope of this disclosure.

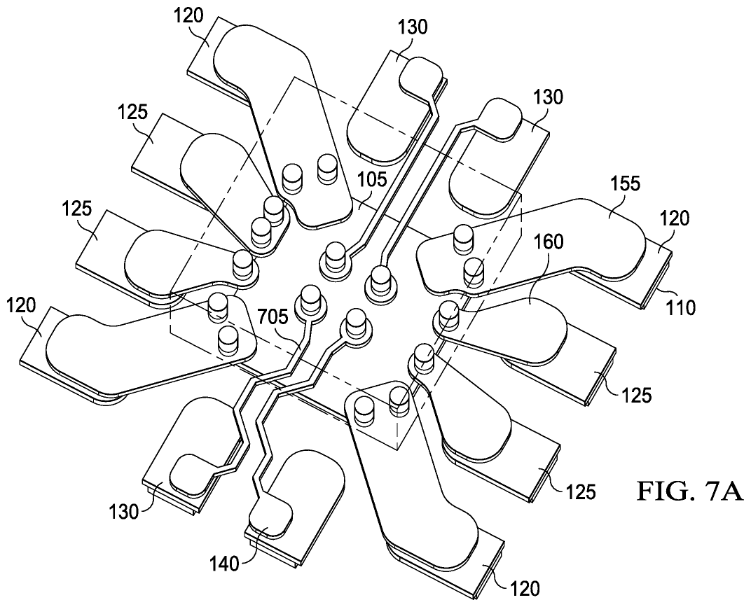

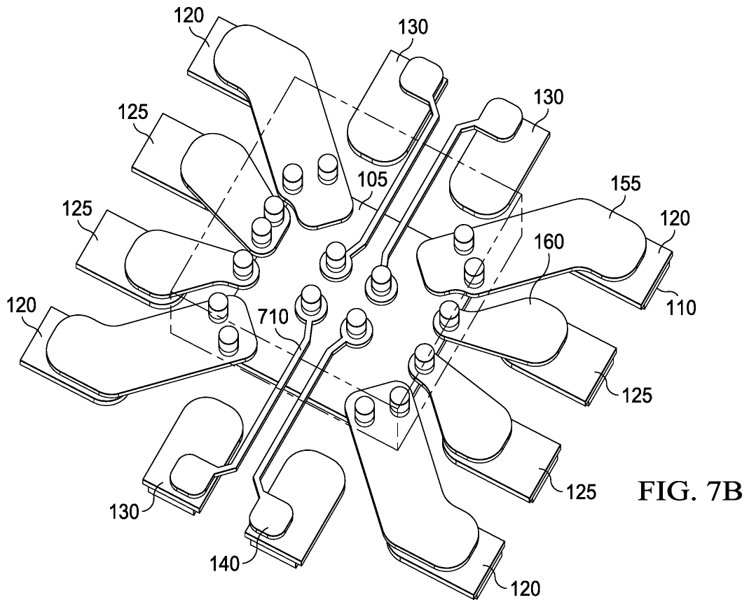

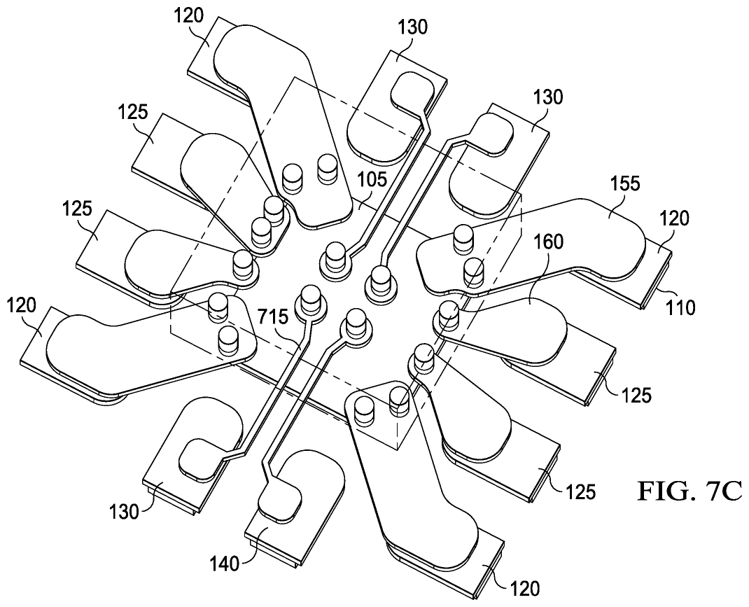

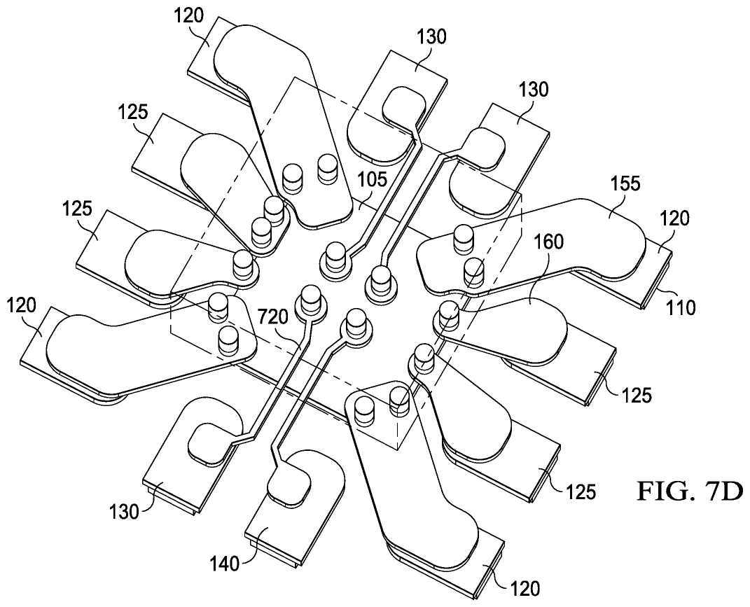

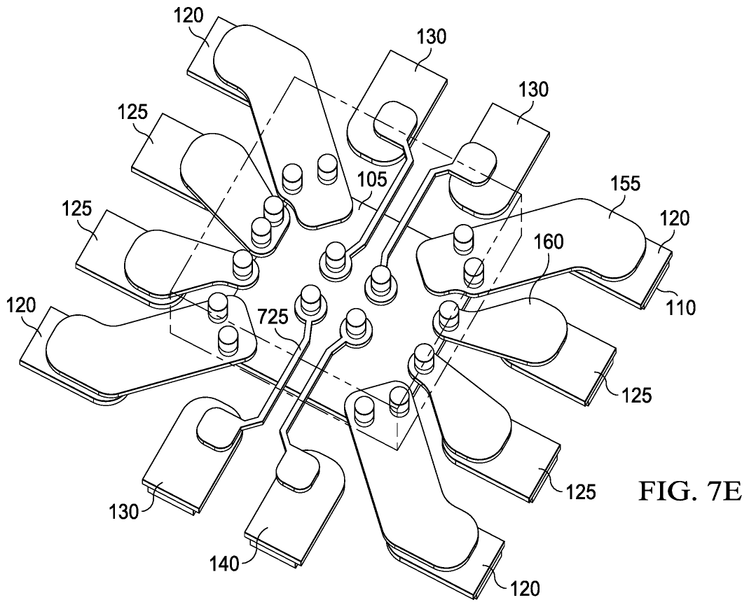

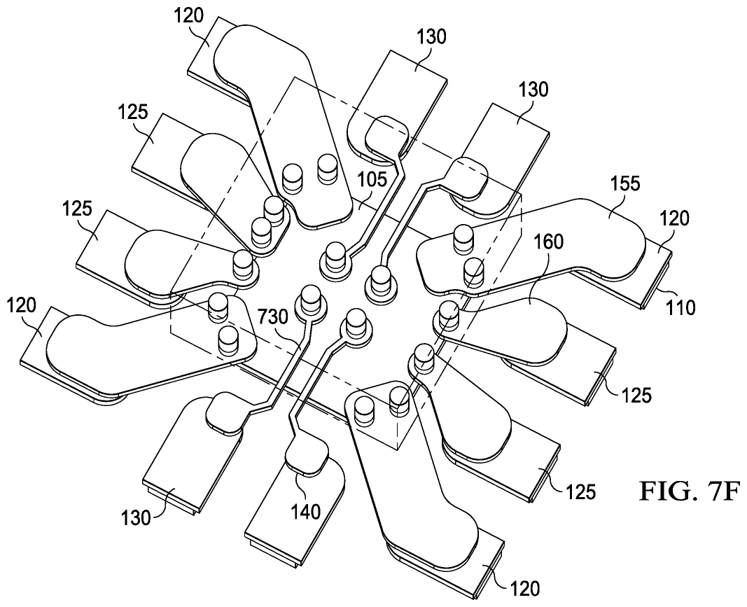

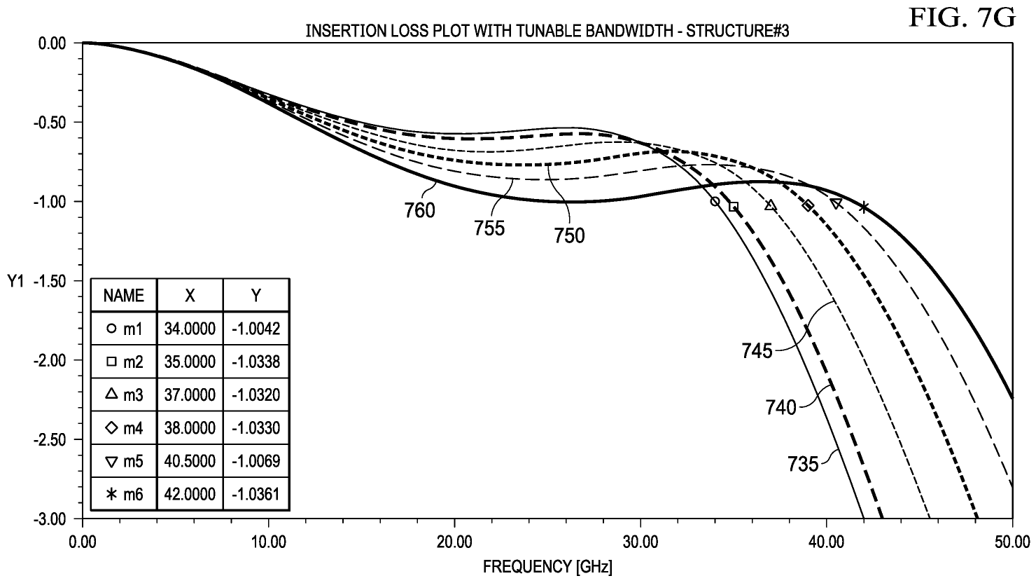

FIGS. 7A-7F are perspective views of various examples of the interconnecting trace 115 and FIG. 7G depicts their electrical performance as a function of frequency. In one example, the length of the interconnecting trace can be varied to achieve a desired electrical performance as a function of frequency. These options include both linear interconnecting traces 710-730, and a non-linear interconnecting trace 705. The non-linear interconnecting trace 705 includes one or more kinks from a top view of the package as shown in FIG. 7A. All of the interconnecting traces in FIGS. 7A-7F may include chamfers. In the example of FIG. 7A, the length of the interconnecting trace 705 is 0.61 mm. In the example of FIG. 7B, the length of the interconnecting trace 710 is 0.55 mm. In the example of FIG. 7C, the length of the interconnecting trace 715 is 0.42 mm. In the example of FIG. 7D, the length of the interconnecting trace 720 is 0.4 mm. In the example of FIG. 7E, the length of the interconnecting trace 725 is 0.32 mm. In the example of FIG. 7F, the length of the interconnecting trace 705 is 0.25 mm. The lengths of various interconnecting traces illustrated in FIGS. 7A-7F may vary with manufacturing and tolerances of +/−10% are within the scope of this disclosure. In one example, varying the dimensions of bypass trace 135, interconnecting trace 115, or the via pad (signal) 140 individually, or all together, or in combination achieves DC up to 100 GHz if the package size varies. The semiconductor package illustrated in various examples is electrically connected to a substrate such as printed circuit board (PCB), or any other suitable substrates with electrical and insulating portions to enable electrical connections between the example semiconductor packages of this disclosure with other electrical components for a particular application, for example, a 5G mobile application.

A thermal performance of various examples of the disclosure compared to a regular wirebond QFN shows significant improvements. For a 0.65 power dissipation evenly distributed on the die, with no thermal vias in the PCB to which the semiconductor package is electrically connected to, and in 85 degree Celsius ambient temperature, maximum die temperature, effective Theta-JA, effective Psi-JB, and effective Psi-JT for a wirebond QFN are 154.2 degree Celsius, 106.3 degree Celsius/W, 57.8 degree Celsius/W, and 2.7 degree Celsius/W respectively. The effective Theta-JA, effective Psi-JB, and effective Psi-JT for an RLF QFN according to various examples of the disclosure are 144.6 degree Celsius, 91.5 degree Celsius/W, 38.8 degree Celsius/W, and 2.1 degree Celsius/W respectively. Therefore, the RLF QFN demonstrates significant improvement in thermal performance compared to standard wirebond QFN.

Various examples of the disclosure are illustrated with RLF QFN packages. These examples can be implemented in other packages such as dual-flat no-leads (DFN) devices that physically and electrically couple integrated circuits to printed circuit boards. Flat no-lead devices, also known as micro leadframe (MLF) and small outline no-leads (SON) devices, are based on a surface-mount technology that connects integrated circuits to the surfaces of printed circuit boards without through-holes in the printed circuit boards. Perimeter lands on the package provide electrical coupling to the printed circuit board. Another example may include packages that are entirely encased in mold compound, such as a dual inline package (DIP).

Modifications are possible in the described embodiments, and other embodiments are possible, within the scope of the claims.

What is claimed is:

1. A semiconductor package comprising:
a die attach pad and a plurality of leads;
a die attached to the die attach pad and electrically coupled to the plurality of leads, wherein the plurality of leads includes power leads and signal leads;
an interconnecting trace electrically coupled between a bond pad of the die and a via-pad;
a via coupled to the via-pad, and the via pad coupled to one of the signal leads; and
a bypass trace including a proximal end connected to the interconnecting trace and a distal end floating inside a mold compound of the semiconductor package.

2. The semiconductor package of claim 1, wherein the distal end of the bypass trace is not directly connected to any electrical structure of the semiconductor package.

3. The semiconductor package of claim 1, wherein the distal end is adjacent to an edge of the semiconductor package.

4. The semiconductor package of claim 1, wherein the bypass trace is non-linear from a top view of the semiconductor package.

5. The semiconductor package of claim 1, wherein the bypass trace includes one or more kinks or chamfers.

6. The semiconductor package of claim 1, wherein the bypass trace is linear.

7. The semiconductor package of claim 1, wherein a dimension of the bypass trace impacts an electrical performance as a function of frequency of the semiconductor package.

8. The semiconductor package of claim 1, wherein the die attach pad and the plurality of leads are part of a routable leadframe.

9. The semiconductor package of claim 1, wherein the interconnecting trace and the bypass trace are coplanar from at least one view of the semiconductor package.

10. The semiconductor package of claim 1 further comprising a power trace electrically connecting between a power bond pad of the die to a power lead, wherein a width of the power trace is more than a width of the interconnecting trace from a top view of the semiconductor package.

11. The semiconductor package of claim 1, wherein a length of the bypass trace is between 0.75 mm and 1.5 mm with a tunable range between 26 GHz and 34 GHz.

12. The semiconductor package of claim 1, wherein a length of the interconnecting trace is between 0.61 mm to 0.25 mm with a tunable range between 34 GHz and 42 GHz.

13. The semiconductor package of claim 1, wherein a length of the bypass trace is between 0 mm to 0.5 mm with a tunable range between 34 GHz and 42 GHz.

14. The semiconductor package of claim 1 further comprising at least one signal interconnecting trace without a bypass trace.

15. A semiconductor package comprising:
a die attach pad and a plurality of leads;
a die attached to the die attach pad and electrically coupled to the plurality of leads, wherein the plurality of leads includes a power lead and a signal lead;
a signal interconnecting trace electrically coupled between a signal bond pad of the die and a signal via pad;
a power interconnecting trace electrically coupled between a power bond pad of the die and a power via pad, wherein the signal via pad is large in dimension than the power via pad; and
a signal via between the signal via pad and the signal lead, and a power via between the power via pad and the power lead.

16. The semiconductor package of claim 15, wherein the signal via pad is large in length than the power via pad from a top view of the semiconductor package.

17. The semiconductor package of claim 15, wherein a length of the signal via pad impacts an electrical performance as a function of frequency of the semiconductor package.

18. The semiconductor package of claim 15, wherein the die attach pad and the plurality of leads are part of a routable leadframe.

19. The semiconductor package of claim 15, wherein signal interconnecting trace is non-linear from a top view of the semiconductor package.

20. The semiconductor package of claim 15, wherein the dimension of the signal via pad impacts an electrical performance as a function of frequency of the semiconductor package with a tunable range between 34-42 GHz range.
